(19) United States
(12) Patent Application Publication
(10) Pub. No.: US 2013/0181193 A1
(43) Pub. Date: Jul. 18, 2013

(54) ORGANIC LIGHT EMITTING DEVICE AND METHOD FOR MANUFACTURING THE SAME

(71) Applicant: Electronics and Telecommunications Research In, Daejeon (KR)

(72) Inventor: Jaehyun MOON, Daejeon (KR)

(73) Assignee: Electronics and Telecommunications Research Institute, Daejeon (KR)

(21) Appl. No.: 13/692,153

(22) Filed: Dec. 3, 2012

(30) Foreign Application Priority Data
Jan. 18, 2012 (KR) 10-2012-0005619

(51) Int. Cl. H01L 51/52

(52) U.S. Cl. CPC H01L 51/52
USPC 257/40; 438/42

(57) ABSTRACT

Provided is an organic light emitting device. The organic light emitting devices includes: a light emitting part where a first electrode, an organic light emitting layer, and a second electrode are stacked ; and a thin film layer having a plurality of holes and micro-resonating the light emitted from the organic light emitting layer.

### CROSS-REFERENCE TO RELATED APPLICATIONS

This U.S. non-provisional patent application claims priority under 35 U.S.C. §119 of Korean Patent Application No. 10-2012-0005619, filed on Jan. 18, 2012, the entire contents of which are hereby incorporated by reference.

### BACKGROUND OF THE INVENTION

The present invention disclosed herein relates to an organic light emitting device and a method for manufacturing the same, and more particularly, to an organic light emitting device capable of providing reliable light extraction and a method for manufacturing the same.

An organic light emitting device, for example, an organic light emitting diode is a light emitting device, where excitons occur when holes supplied from an anode electrode and electrons supplied from a cathode electrode are combined in an organic light emitting layer therebetween and they are recombined again. The organic light emitting diode as a self-light-emitting device is applied to a display device and developed due to its wide viewing angle, fast response sped, and high color reproduction rate. Furthermore, recent research and development on applying an organic light emitting diode are actively in progress.

FIG. 1 is a schematic view illustrating a layer stacked structure of a typical organic light emitting diode. The organic light emitting diode includes a sequentially stacked substrate 10, anode (i.e. a transparent electrode) 20, organic light emitting layer 30, cathode (i.e. a reflective electrode) 40, and protective layer 50.

The organic light emitting diode may be configured to emit R (red), G (green), and B (blue) separately, or to emit white color only. At this point, in order to express a desired color, a plurality of organic light emitting layers emitting a light of different wavelengths may be combined and used.

Korea Patent Application Publication No. 2007-0008071 discloses a technique that increases brightness and makes pixelization easy by stacking the widths of organic light emitting structures uniformly and vertically in order to make an area of a RGB sub pixel identical to that of a pixel. However, by such a structure, the light generated from a sub pixel at the middle is reflected at a sub pixel at the end, and then is emitted toward the external. As a result, light efficiency is deteriorated.

### SUMMARY OF THE INVENTION

The present invention provides an organic light emitting device capable of providing reliable light extraction and a method for manufacturing the same.

Embodiments of the present invention provide organic light emitting devices including: a light emitting part where a first electrode, an organic light emitting layer, and a second electrode are stacked; and a thin film layer having a plurality of holes and micro-resonating the light emitted from the organic light emitting layer.

The thin film layer may include metal.

The thin film layer may be disposed on the first electrode.

The thin film layer, the first electrode, and the organic light emitting layer may be sequentially stacked.

The first electrode may include an upper first electrode and a lower first electrode; and the thin film layer may be disposed between the lower first electrode and the upper first electrode.

The thin film layer may have a thickness of about 20 nm to about 100 nm.

The hole may have a diameter of about 100 nm to about 500 nm.

The second electrode comprises a metal layer having a plurality of holes

The second electrode comprises a metal mirror layer.

In still other embodiments of the present invention, methods of manufacturing an organic light emitting device include: forming a lower first electrode; distributing colloidal beads on the lower first electrode; growing a thin film layer by depositing metal on the lower first electrode; forming a plurality of holes in the thin film layer by removing the colloidal beads, and forming an upper first electrode, an organic light emitting layer, and a second electrode sequentially on the thin film layer.

The thin film layer may have a thickness less than a height of the colloidal beads scattered on the lower first electrode.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a schematic view illustrating a layer stacked structure of a typical organic light emitting diode;

FIG. 2 is a schematic view illustrating an organic light emitting device according to an embodiment of the present invention;

FIG. 3 is a schematic view illustrating a structure of a white OLED device including a light emitting layer of two layers;

FIG. 4 is a schematic view illustrating an operating principle of a triplet harvesting type hybrid white OLED;

FIG. 5 is a schematic view illustrating a structure of a direct recombination type hybrid white OLED;

FIG. 6 is a schematic view illustrating a light extraction principle of a micro lens array;

FIG. 7 is a schematic view illustrating a principle of a micro-resonator using a bragg minor;

FIG. 8 is a schematic view illustrating an organic light emitting device according to an embodiment of the present invention;

FIG. 9 is a schematic view illustrating a simple micro-resonator structure;

FIG. 10 is a plan view illustrating a thin film according to an embodiment of the present invention;

FIG. 11 is a schematic view illustrating an organic light emitting device according to another embodiment of the present invention; and

FIGS. 12A to 12G are schematic views illustrating processes for manufacturing an organic light emitting device according to an embodiment of the present invention.

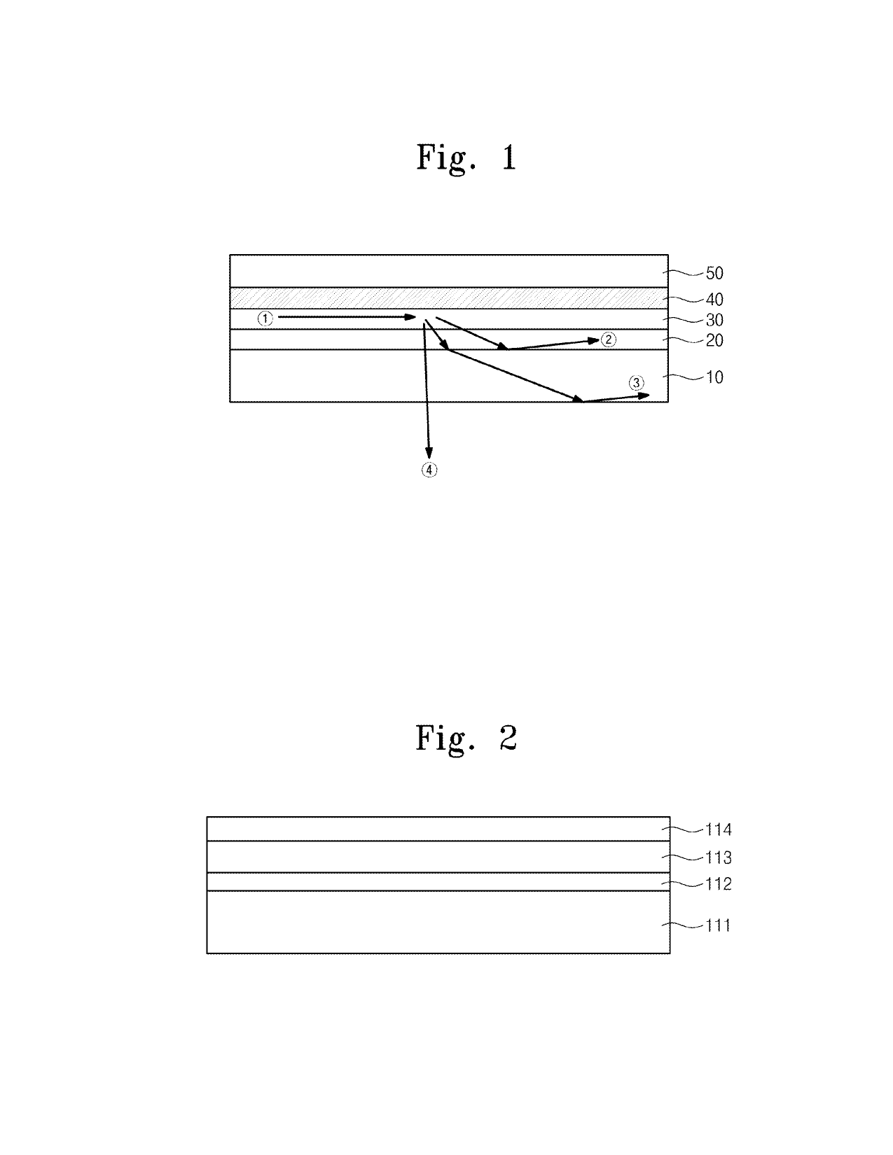

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

Hereinafter, it will be described about an exemplary embodiment of the present invention in conjunction with the accompanying drawings.

FIG. 2 is a schematic view illustrating an organic light emitting device according to an embodiment of the present invention.

The organic light emitting device of FIG. 2 includes a substrate 111, a first electrode 112, an organic light emitting layer 113, and a second electrode 114, which are sequentially stacked.

The substrate 111 provides a mechanical support to the organic light emitting device and also serves as a transparent window. The substrate 111 may be formed of glass or plastic having light transmitting property. In the case of plastic, polyethylene terephthalate (PET), polycarbonate (PC), and poly ethersulfone (PES), polyimide (PI) may be used.

The first electrode 112 may be an anode or a cathode. For convenience of description, it is assumed hereinafter that the first electrode 112 is an anode and a transparent electrode of ITO.

The second electrode 114 has a polarity that is paired with the first electrode 112. For example, if the first electrode 112 is an anode, the second electrode 114 is a cathode, and if the first electrode 112 is a cathode, the second electrode 114 is an anode.

The organic light emitting layer 113 is an element which includes organic matter and generates light by using the power provided from the first electrode 112 and the second electrode 114. For example, an Organic Light Emitting Diode (OLED) is a self-light-emitting type device that generates a light of a specific wavelength as electrons and holes are recombined in the organic light emitting layer 113 in order to emit energy when electric filed is applied. A basic structure of the OLED includes an anode (i.e. an ITO layer), a hole injection layer, a hole transfer layer, a light emitting layer, an electron transfer layer, an electro injection layer, and a cathode (i.e. a metal electrode), which are in the order close to the substrate 111. Hereinafter, a layer between the both electrodes 112 and 114 (more specifically, i.e. a hole injection layer, a hole transfer layer, a light emitting layer, an electron transfer layer, and an electron injection layer) is designated as an organic light emitting layer.

The organic light emitting layer is a key element for lighting source. Based on a device structure, there may be a stack structure, a single light emitting layer structure, a horizontal RGB structure, and a down conversion structure. Among them, the stack structure is typically used because it is easily manufactured and high efficiency is obtained. Additionally, according to a material used, there may be fluorescence, phosphorescence, and hybrid white OLED. If fluorescence is used, device stability may be excellent but high efficiency may be hardly obtained. Also, if phosphorescence is used, high efficiency may be obtained but stable blue color may be hardly obtained. As efforts to complement two materials' issues, research on a hybrid method, which uses fluorescence as blue color and uses phosphorescence as other colors, is being actively in progress.

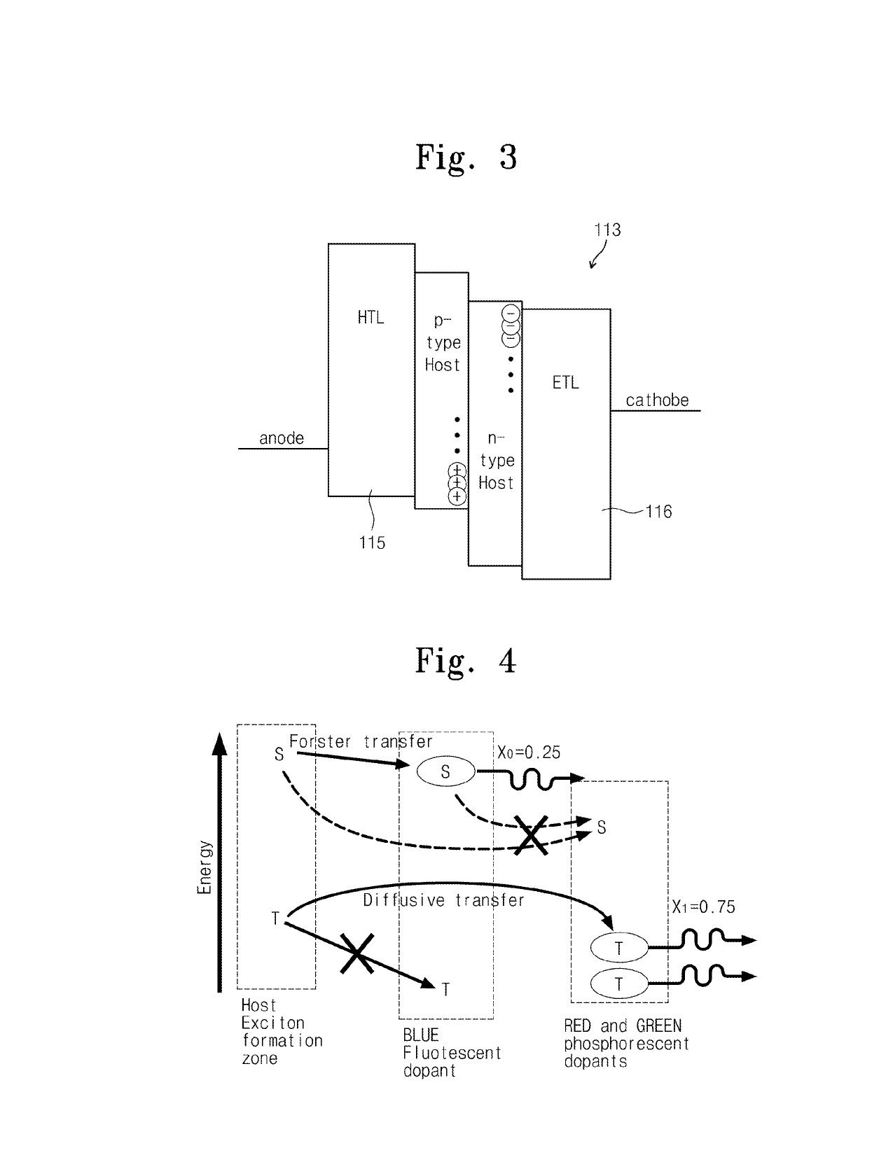

As shown in FIG. 3, which illustrates a structure of a white OLED device, a structure of a phosphorescence device includes a two-layer light emitting layer 113 as a basic frame, in addition to a hole injection/transfer layer 115 and an electron injection/transfer layer 116. Here, the light emitting layer 113 includes a p-type host and an n-type host, each with a HOMO/LUMO structure having a high hole injection and electron injection barrier. Such a structure may be similar to that of a PN junction in an LED, and current loss may be minimized by limiting a recombination zone within the two hosts. At this point, materials are required to have higher triplet energy than blue phosphorescent dopant and not too low hole mobility or electron mobility in addition to electrical/chemical/thermal stabilities. Here, if there is a material for a hole transfer layer or an electron transfer layer, which has high charge mobility and higher triplet energy than blue phosphorescent dopant, a high degree of freedom in designing a device structure may be provided.

The key to develop a phosphorescent white OLED device is to develop a new material having wide triplet energy. It is important to have wide triplet energy that maintains existing charge mobility and stability in a hole transfer layer and an electron transfer layer in addition to a host, and does not dissipate the triplet energy of a blue phosphorescent dopant. Furthermore, it is also important to reduce the number of dopants in order to obtain manufacturability. In order to obtain a wide color reproduction range, a dopant having narrow spectrum is preferably used as a dopant for display. In order to obtain a high color rendering index number with the small number of dopants, a dopant having wide spectrum is preferably used as a dopant for lighting. Accordingly, the development of an OLED material for lighting is required separated from that of an OLED material for display.

Furthermore, a hybrid white OLED is an element that replaces phosphorescence, which causes blue color issue in blue color phosphorescent white OLED device, with fluorescence. The hybrid while OLED may be classified into a triplet harvesting type and a direct recombination type.

First, the triplet harvesting type is a very attractive method in that it can theoretically change all current into light energy. That is, since the triplet harvesting type could obtain efficiency and device stability like a phosphorescent white OLED, it has drawn much attention from researchers. In relation to the principle that such a type device operates, as shown in FIG. 4, which illustrates the operation principle of a triplet harvesting type hybrid white OLED, most of the recombination in a fluorescent layer, and accordingly, blue light emission is obtained by the singlet exciton of the fluorescent layer. A triplet, which is not used in the recombination zone of the fluorescent layer, transfers to a phosphorescent layer through diffusive transfer, thereby obtaining green and red phosphorescent emission. With such a principle, the singlet of about 25% is converted into the blue light emission of the fluorescent layer and the triplet of the remaining about 75% is converted into the green/red light of the phosphorescent layer, so that 100% conversion efficiency may be achieved.

The important issue in such a device is to control a recombination zone to be limited to the fluorescent layer, and adjust energy transfer in order to allow triplet excitons to occur only in the phosphorescent layer. Such a type hybrid device may not be substantially used due to demanding operational conditions. That is, since the triplet excitons of the fluorescent layer need to transfer to the phosphorescent layer to the maximum without loss, a path for that becomes extinct by a non light emitting process in the fluorescent layer, or becomes extinct after transferring from the phosphorescent layer to the fluorescent layer again. That is, extinct paths need to be considered. At this point, since information on conditions for generating a desired path faster than other extinct paths is insufficient, it is difficult to design and expect a device.

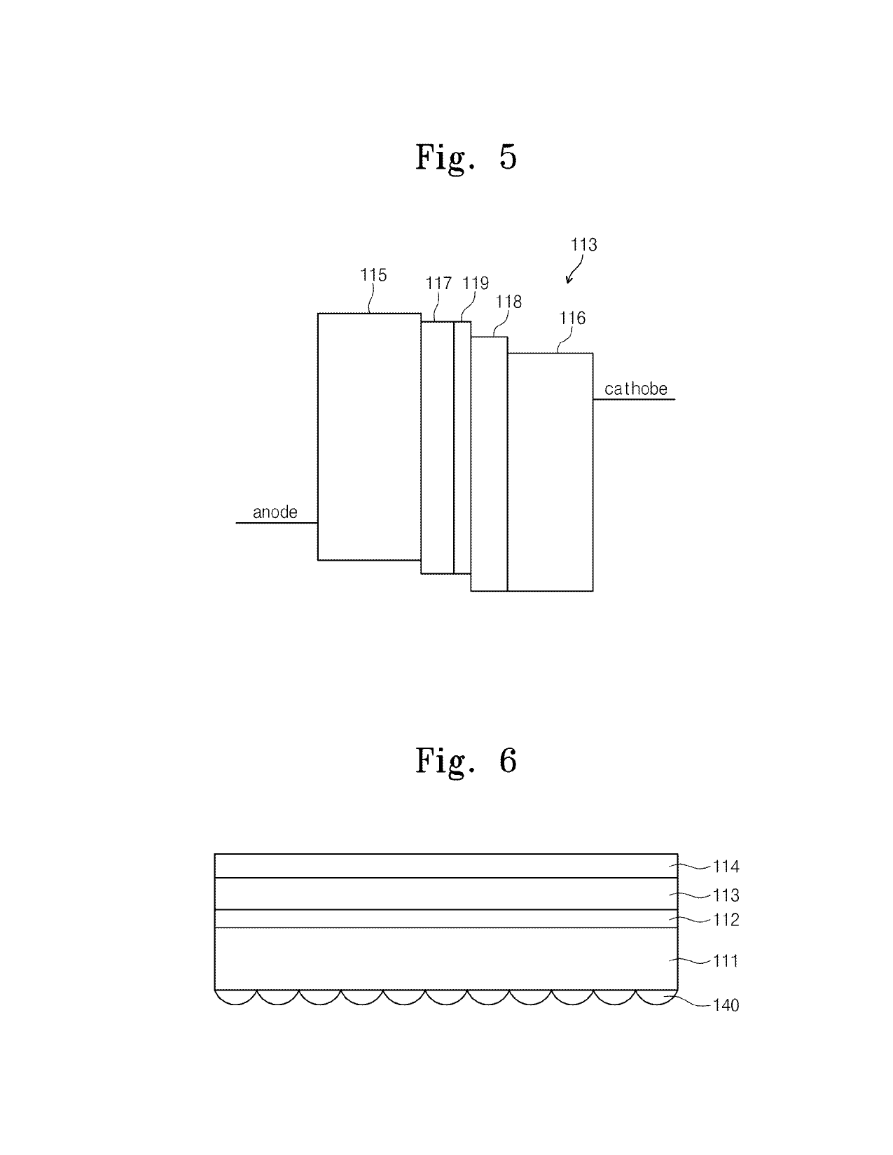

As shown in FIG. 5, which illustrates a direct recombination type hybrid white OLED structure, this type device uses a method through which light emission is obtained from both fluorescence and phosphorescence by forming a recombination zone in both the fluorescent layer 118 and the phosphorous layer 117 through adjustment. Since the triplet excitons of the blue fluorescent layer may not be used, efficiency may be lower compared to the above-mentioned triplet harvesting type. However, this type device may utilize a wide variety of materials and may have a structure having a high degree of freedom in designing a device. In this type device, the role of an interlayer 119 that separates a fluorescent layer from a phosphorescent layer is very important. That is, the interlayer 119 serves to adjust a recombination zone to be formed over a fluorescent layer and a phosphorescent layer, and also serves to prevent the triplet excitons of a phosphorescent layer from transferring to a fluorescent layer and becoming extinct.

As another challenge that needs to be overcome in an organic light emitting device such as the above-mentioned OLED, there is a light extraction issue.

As mentioned above, a material used for a light emitting layer in an OLED includes fluorescence and phosphorescence. Since a phosphorescent OLED may use all excitons, which are generated through recombination, for light emission, a theoretical internal quantum efficiency is 100%. That is, the efficiency is about four times than that of a fluorescent OLED, but the material has a short life cycle. However, due to the active development of phosphorescent materials, their internal quantum efficiency and life cycle are greatly improved, and thus, they are now used in commercial products. However, even if the internal quantum efficiency of an OLED is about 100%, only about 20% of the emission amount is emitted the external, about 80% thereof is lost due to a wave-guiding effect resulting from a refractive index difference between the substrate 111 and the ITO first electrode 112 and organic light emitting layer 113 and a total reflection effect resulting from a refractive index difference between the substrate 111 and air.

A refractive index of the organic light emitting layer 113 is about 1.6 to about 1.9, and a refractive index of ITO typically used as an anode is about 1.9 to about 2.0. The two layers have a thin thickness of about 100 nm to about 400 nm, and a refractive index of glass typically used as the substrate 111 is about 1.5. Thus, a planar waveguide is naturally formed. According to calculations, the light lost in an internal guided mode due to the above reason is about 45%. Additionally, since the refractive index of the substrate 111 is about 1.5 and the refractive index of air is about 1.0, the light incident at an angle greater than a critical angle is total-reflected when escaping from the substrate 111 to the external, and thus is tripped in a substrate inside. Since the light trapped therein is about 35%, only about 20% of the emission amount is emitted to the external.

Due to such a low light extraction efficiency, the external light efficiency of an OLED stays in a low level. Therefore, a light extraction technique becomes a core technology that improves the efficiency, brightness, and life cycle of an OLED lighting panel.

A technique for extracting the trapped light from an organic light emitting layer/ITO layer to the external through a refractive index difference between an anode (i.e. ITO) and a substrate is called internal light extraction, and a technique for extracting the trapped light from a substrate to the external (i.e. air) is called external light extraction.

In relation to the external light extraction, the improvement of realistic light efficiency is limited to about 1.6 times and color change occurrence according to a viewing angle, which results from diffraction phenomenon, needs to be minimized The external light extraction technique includes a method of forming a Micro Lens Array (MLA), an external scattering layer, and an anti-reflective film.

The internal light extraction technique may theoretically improves external light efficiency more than about three times, but affects an internal OLED interface surface very sensitively. Therefore, in addition to optical effect, electrical, mechanical, and chemical characteristics should be satisfied. The internal light extraction technique includes a method of forming an internal scattering layer, a substrate surface modification, a refractive index adjusting layer, a photonic crystal, and a nano structure.

In relation to the external light extraction, the MLA includes to a plurality of lenses, which are two-dimensionally disposed on a plane of a flat substrate that faces air. Each lens has a diameter of less than about 1 mm. As shown in FIG. 6, which illustrates a light extraction principle of the MLA, since an incident angle of light with respect to the surface tangent of the micro lens 140, which is curved than a plane, becomes less than a critical angle, the light is not trapped by total reflection and is extracted to the external. A medium of the MLA is made of a material having the same refractive index as the substrate 111 and has a diameter of several tens of μm. as the density of the micro lens 140 becomes higher, light extraction efficiency is increased, and according to the shape of a lens, light distribution is changed. When an external light extraction structure is attached to the substrate external by using the MLA, efficiency increase of about 50% is provided.

In the external light extraction, an external scattering layer may be manufactured in a sheet shape and then is attached to the substrate external through a similar method of forming an MLA sheet. Or, an external scattering layer may be manufactured by coating a substrate with a manufactured solution and hardening the coated substrate. Since there is no color change and interference color according to a viewing angle in the external scattering layer and Lambertian distribution is maintained after light passes through a light scattering layer, this light extraction structure may be applicable to a white OLED lighting panel. However, if a light scattering layer becomes thicker and light scattering particles form a multi layered structure, scattering effect of a short wavelength becomes greater than that of a long wavelength so that a transmission color has yellowish red. This should be taken care of. In order to minimize a spectrum change due to a scattering effect difference according to a wavelength, the refractive index, size, and density of scattering particles and also the refractive index and absorption spectrum of materials need to be adjusted. In an external fluorescent colloid structure, a ratio of the absorbed light to the scattering and re-emitting light may vary sensitively according to a thickness, a fluorescent size, and a concentration, so that it should be designed carefully. It may be effective to form a light scattering layer by using a polymer sheet containing small air bubbles. Since the refractive index of air bubble is about 1.0 and the refractive index of a material is about 1.5, there is a great refractive index difference, and thus, light scattering effect becomes larger. Therefore, it is advantageous to minimize spectrum change by relatively minimizing the thickness of a light scattering layer.

In the external light extraction, an anti-reflective film refers to a layer, which is formed by thinly stacking one-to-three layers of materials such as dielectic substances on the section of an optical device, in order to remove the light reflection due to a drastic refractive index change at the section of the optical device and increase the amount of transmitting light. When light reflection occurs two times (i.e. when the light is incident to a glass substrate and is transmitted through it), the light of about 8% is lost. In the OLED, because of a device structure, if light is emitted to the external air, one time reflection occurs. Thus, light extraction efficiency may be increased by about 4% when an anti-reflective film is used for external light extraction. When the minimum reflection of perpendicularly-incident light is required in relation to a single wavelength light, a material having a refractive index corresponding to the square root of a refractive index of a substrate for deposition is deposited with a thickness of the one-fourth wavelength of the material. However, if the minimum refractive index is required with respect to several wavelengths in a visible ray area, several layers of different materials may be deposited.

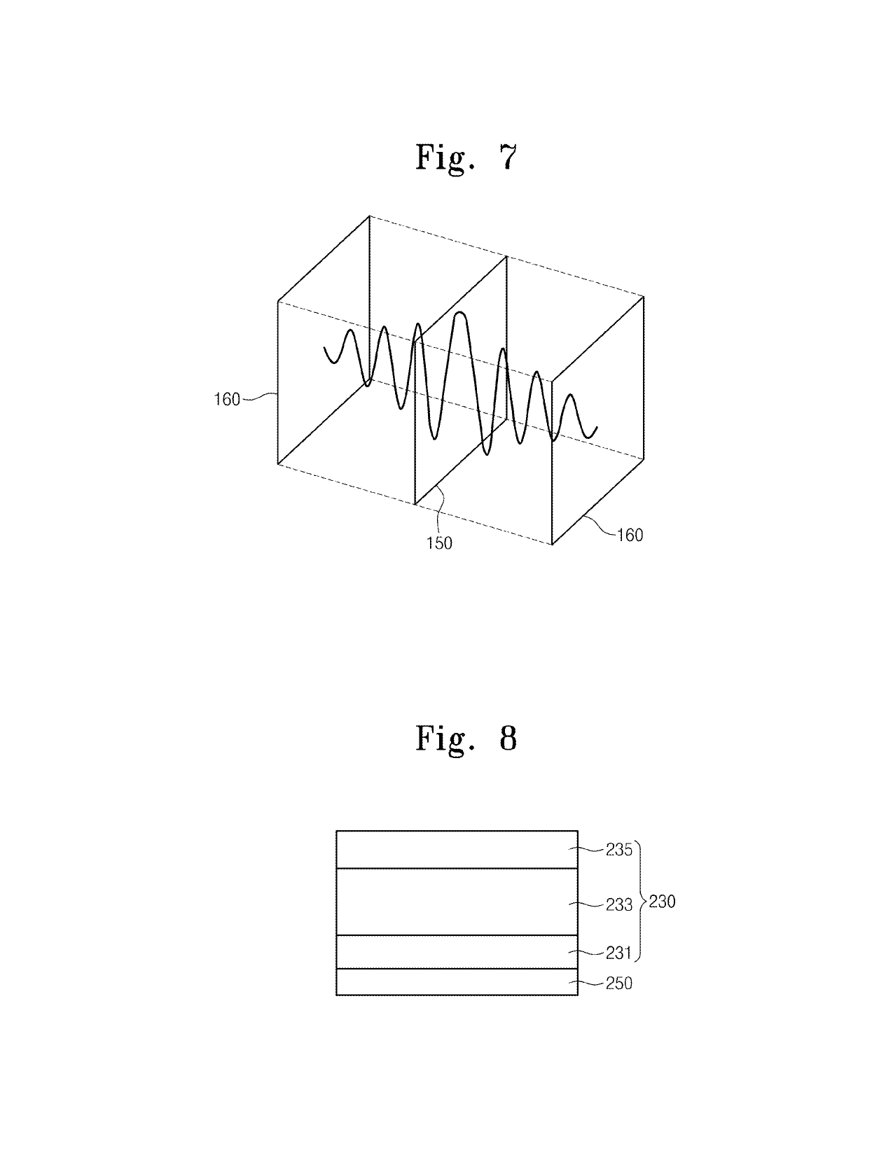

In the internal light extraction, a micro-resonator is also called micro-cavity. As shown in FIG. 7, which illustrates the principle of the micro-cavity using a Bragg mirror, a spacer layer 150 is disposed between the brag mirrors 160 or metal mirror layers in order to generate resonance.

Since the thickness of the spacer layer 150 has the size of a wavelength that generates standing waves of visible ray, the term “micro” is given. In the OLED, the micro-cavity includes a strong cavity and a weak cavity. The OLED includes a weak cavity structure without specially designing a cavity structure. As a basic structure, an organic light emitting layer having a refractive index of about 1.6 to about 1.9 is stacked at the center with a thickness of several hundreds of nm, and an ITO (for example, an anode) layer and metal cathode layer having a refractive index of about 1.9 are stacked at the both of the organic light emitting layer, so that a natural micro-cavity structure is formed. Therefore, light extraction efficiency varies greatly according to a thickness of an organic light emitting layer and a thickness of an ITO layer. Especially, as a relative position of a recombination zone changes, a ratio of a light extraction mode with respect to an internal/external guided mode changes from about 22% into about 55%.

Additionally, if the thickness of a cathode exceeds by λ/4 with respect to a wavelength λ of light, light extraction efficiency is decreased, so that it may be less than λ/4.

A tandem structure using an organic light emitting layer as a multi layered structure may use a micro-cavity structure variously, and thus, may be used in manufacturing a color modulation OLED panel. In relation to the micro-cavity structure, before each layer of an OLED device is deposited, a Bragg mirror layer is deposited through a similar deposition method, and each layer's thickness is adjusted. Therefore, there is no need to worry about surface abnormality due to a light extraction structure, and the micro-cavity structure is easily applicable to panel production. However, there is a big limitation in using the micro-cavity structure for the internal light extraction of an OLED lighting panel. That is, all micro-cavities necessarily accompany spectrum narrowing. As a strong micro-cavity structure is used more, spectrum narrowing becomes stronger, so that only the light in a very narrow wavelength area is emitted strongly. However, the light emitting efficiency of the light having a wavelength not in a corresponding wavelength area is reduced.

Accordingly, in the case of an OLED lighting panel using a white OLED device, when the micro-cavity structure is used, the light emission color of the panel may easily deviate from a white color range. Also, since light extraction efficiency is decreased in an area other than a specific wavelength area, total light extraction efficiency may be decreased. Micro-cavity effect may be applied to a display panel that emits each RGB color, or a single color OLED panel.

Photonic crystal in the internal light extraction refers to a structure, in which two materials having different dielectric constants are arranged in a nm scale in order to allow or prevent transmission according to the wavelength of light, thereby only transmitting or reflecting only the light of a specific wavelength. Herein, a prohibited wavelength zone is called a photonic band gap. Through this phenomenon, it is possible to manufacture an optical device that may change an optical path with almost no loss. The photonic crystal has three types including a one dimensional photonic crystal (which is called a Bragg grating), a two dimensional photonic crystal (where embossing projections are arranged on a plane periodically, and a three dimensional photonic crystal. The photonic crystal uses the diffraction of light. That is, when a photo crystal structure is disposed on a planar optical waveguide formed in an OLED inside in order to prevent the light from being transmitted in a plane direction, a prevention band is formed. Therefore, the light generated in an organic light emitting layer does not form a guided mode so that it is emitted to the external. Through this phenomenon, a two dimensional photonic crystal structure is formed in an OLED, thereby improving light extraction efficiency. However, the two dimensional photonic structure may be applied to a single color OLED but may increase the light extraction efficiency of a specific wavelength in an OLED lighting panel using a white OLED.

Since an internal scattering layer in the internal light extraction has no color change according to a viewing angle and Lambertian distribution occurs therein basically, uniform brightness is provided in a panel. Additionally, since a scattering layer is formed by mixing different types of materials and coating a glass substrate with the mixed material, its manufacturing processes are relatively simple. When the scattering layer is applied, light extraction efficiency is increased more compared to there is no light scattering layer. Moreover, less color changes according to a viewing angle and similar Lambertian distribution are provided. However, there should be sufficient scattering centers in order to maximize a scattering effect, but when there are too much scattering centers, since back scattering is also increased, the possibility that scattered light is absorbed in an organic light emitting layer is increased. Accordingly, only when scattering and internal absorption are optimized, light extraction efficiency is increased. However, this is the assumed case that there is no light absorption in the scattering layer. In most cases, when there is absorption in a scattering layer, the light efficiency increase due to light extraction effect is reduced due to the absorption of the scattering layer. Even if the absorbance of the scattering layer is less than about 0.1, light efficiency deterioration rather than light extraction effect occurs due to absorption. Therefore, in order to use the scattering layer as an internal light extraction structure, a thin thickness needs to be manufactured to have a visible ray absorption of less than about 0.1.

A nano embossing structure in the internal light extraction is a light extraction structure that takes only advantages of the above-mentioned photonic crystal and scattering layer. As described above, since the photonic crystal structure is used only for a specific wavelength band of light, it is unavailable for a white OLED. Also, since internal absorption occurs inevitably in the scattering layer, light extraction effect is reduced by half. In relation to the nano embossing structure, embossing structures of several hundreds of nm are used for an internal light extraction structure like the photonic crystal, but are arranged irregularly. The arranged nano embossing structures has diffraction effect partially, but serve as a single scattering layer. Therefore, light wavelength dependency, color change according to a viewing angle, and light distribution distortion disappear almost, and also, self absorption becomes almost negligible.

FIG. 8 is a schematic view illustrating an organic light emitting device according to an embodiment of the present invention.

The organic light emitting device shown in FIG. 8 includes a light emitting part 230 (where a first electrode 231, an organic light emitting layer 233, and a second electrode 235 are stacked in order to emit light) and a thin film layer 250 (having a plurality of holes and micro-resonating the light emitted from the organic light emitting layer 233).

The first electrode 231, the organic light emitting layer 233, and the second electrode 235 are sequentially stacked, and an additional layer for performing an additional function may be disposed between each layer. If a transparent substrate such as a glass substrate is applied, it is assumed that the transparent substrate may be stacked on the outer surface of the first electrode 231.

As seen above, as one way of internal light extraction, there is a micro-resonator.

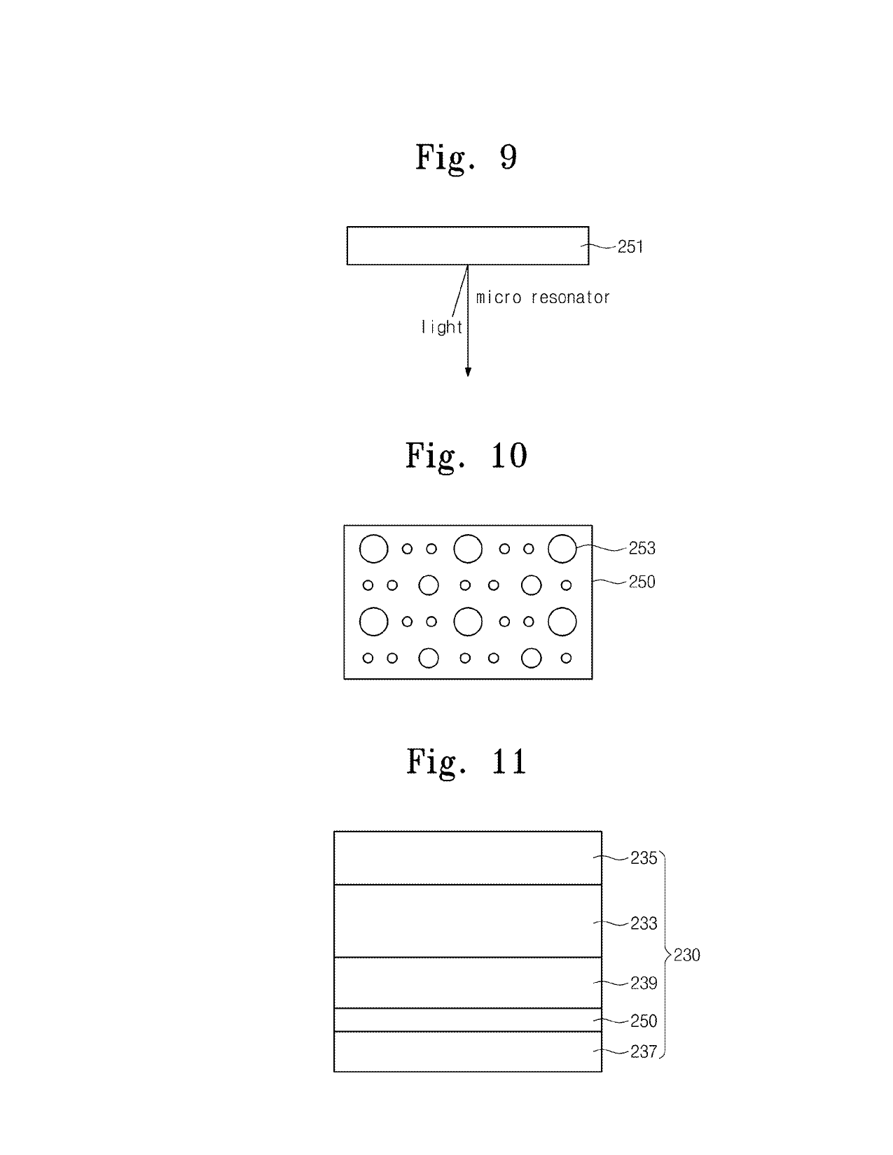

In order to implement a micro-resonator, at least one reflection means 251 for reflecting light is required as shown in FIG. 9. When the first electrode 231 is an anode and the second electrode 235 is a cathode, the second electrode 235, i.e. a cathode, may be a metal electrode. In the case of the metal electrode, one reflection means for a micro-resonator is prepared in order to easily reflect light. That is, the second electrode 231 becomes the above-mentioned metal mirror layer. Here, in order to obtain a reliable micro-resonator, such as two mirror layers disposed as shown in FIG. 7, a Bragg minor layer or a metal minor layer facing the second electrode 235 and the organic light emitting layer 233 are required.

For this, the thin film layer 250 is used.

The thin film layer 250 has a plurality of holes and micro-resonates the light generated from the organic light emitting layer 233. At this point, the plurality of holes in the thin film layer 250 may be formed through a combination of colloidal templating and a deposition process.

For convenience of description, although the second electrode 235 is assumed and described as a metal minor layer, even if the second electrode 235 does not serve as the metal minor layer, a micro-resonator reflecting light once, as shown in FIG. 9, is possible only with the thin film layer 250.

The thin film layer 250 may be disposed on the outer surface of the first electrode 231. When an anode may include a plurality of anode layers, a thin film layer 250 may be disposed between each anode layer.

The thin film layer 250 may be disposed between the first electrode 231 and the organic light emitting layer 233. At this point, the outer surface of the first electrode 231 is the opposite side of the surface where the organic light emitting layer 233 is stacked on the first electrode 231. Accordingly, as shown in FIG. 8, according to a structure where each component of the organic light emitting device is stacked from bottom to top, the bottom surface of the first electrode 231 is the outer surface thereof. If the thin film layer 250 is disposed on the outer surface of the first electrode 231, the thin film layer 250, the first electrode 231 and the organic light emitting layer 233 are sequentially stacked.

The second electrode 235 may be a metal electrode having a metal minor layer function. If the thin film layer 250 is formed of metal such as Ag, a reliable micro-resonator is formed between the second electrode 235 and the thin film layer 250 as shown in FIG. 7. However, if a Bragg mirror layer or a metal minor layer for performing a micro-resonance function is used to form the thin film layer 250, it is difficult for the light generated from the organic light emitting layer 233 to be emitted to the external. That is, transparency is deteriorated, and consequently, it is hard to expect reliable light extraction efficiency.

That is, in order to achieve reliable light extraction, the thin film layer 250 should be capable of providing micro-resonance, and in addition to that, should have high transparency. In order to improve transparency, the thin film layer 250 of FIG. 8 includes a plurality of holes 253 as seen from the top, as shown in FIG. 10. By forming the plurality of holes 253 in the thin film layer 250, micro-resonances are provided at the portions excluding the holes 253 and transparency is provided at the holes 253.

At this point, if the hole 253 has a too small size, a light extraction loss due to transparency deterioration is greater than a light extraction gain obtained by micro-resonance. Additionally, if the hole 253 has a too large size, a light extraction loss due to micro-resonance deterioration is greater than a light extraction gain obtained by transparency. Therefore, the size of the hole 253 is required to be set appropriately. According to experiments, an appropriate diameter of the hole 253 may range from about 100 nm to about 500 nm. The shape of the hole 253 may be a closed curve such as a circle.

Additionally, according to characteristics of the thin film layer 250 in the light emitting part 230, the thin film layer 250 is not supposed to affect the generation efficiency of the light generated from the organic light emitting layer 253. Accordingly, the thickness of the thin film layer 250 is also important. According to experiments, the thickness of the thin film layer 250 may range from about 20 nm to about 100 nm.

The arrangement of the holes 253 in the thin film layer 250 may include an ordered arrangement where the sizes/shapes of holes are the same and their arrangement is ordered, a quasi ordered arrangement where the sizes/shapes of holes and their arrangement are periodically changed, and a random arrangement where the sizes/shapes of the holes and their arrangement are random.

FIG. 11 is a schematic view illustrating an organic light emitting device according to another embodiment of the present invention.

In relation to the organic light emitting device of FIG. 11, unlike the thin film 250 disposed on the outer surface of the first electrode 231 as shown in FIG. 8, a multiple overlapped first electrode is provided, and a thin film layer is interposed between each first electrode. As shown in FIG. 11, the first electrode 231 includes a double layer, and the thin film layer 250 is disposed between each first electrode 231. The first electrode 231 may include a lower first electrode 237 and an upper first electrode 239.

If the thin film layer 250 is disposed between the first electrode 231 of a double layer, each layer may be formed in the following order. The lower first electrode 237 is formed as the bottom, and then, the thin film layer 250 is formed on the lower first electrode 237. Then, the upper first electrode 239 is formed on the thin film layer 250. The thin film layer 250 may be disposed between the lower first electrode 237 and the upper first electrode 239.

Moreover, in order to maximize the efficiency of micro-resonance, a minor layer corresponding to the thin film layer 250 may be disposed on the light emitting part 230. At this point, the second electrode 235, i.e. a metal electrode, may serve as a metal mirror layer at the light emitting part 230. At this point, in the case of an organic light emitting device where light is emitted toward a second electrode, the second electrode is required to have transparency. For this, the second electrode 235 may be formed to have a plurality of holes like the thin film layer 250. That is, the second electrode 235 as a metal layer having a plurality of holes may micro-resonate the light emitted from the organic light emitting layer 233, with the thin film layer 250.

In brief, the above-mentioned organic light emitting device includes an organic light emitting layer that emits light and a thin film layer that grows in order to micro-resonate the light emitted from the organic light emitting layer. By forming a plurality of holes in the thin film layer, the transmittance of the emitted light is improved.

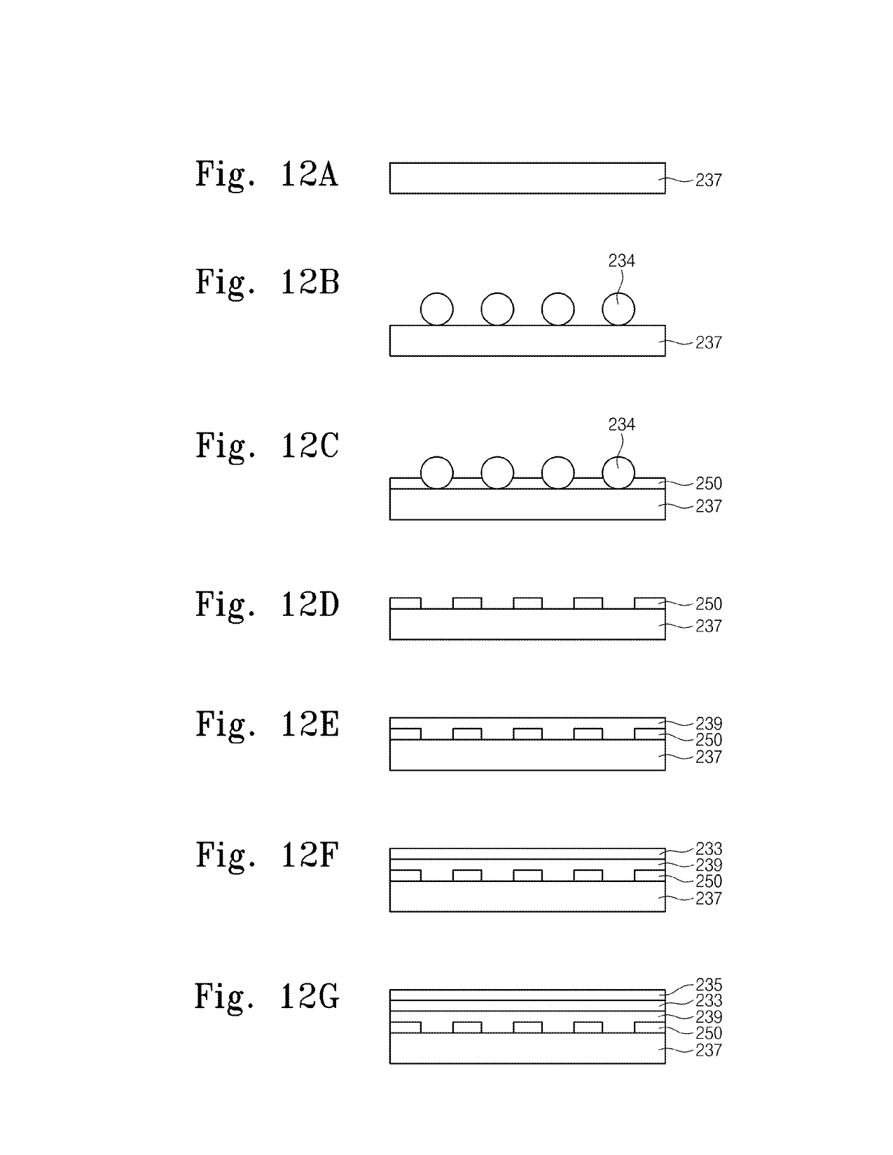

FIGS. 12A TO 12G are schematic views illustrating processes for manufacturing an organic light emitting device according to an embodiment of the present invention.

First, a transparent thin film corresponding to the lower first electrode 237 is formed. (refer to FIG. 12A)

Referring to FIG. 12B, colloidal beads 234 are dispersed on the transparent thin film. In order to form holes in a metal layer, the colloidal beads 234 are formed on the transparent thin layer. Since it is difficult to directly scatter polymer beads on the transparent thin film, the polymer beads are converted into a colloidal state, and then, the colloidal beads 234 are dispersed. Then, through drying and heating processes, when the colloidal liquid components evaporate, only the polymer beads remain.

A layer formed of the polymer beads may be formed with a monolayer. After the bead monolayer is formed, a process to reduce the size of beads is performed through an etching process, in order to obtain a physical space between the beads. A process to reduce the size of beads may include an etching process.

Referring to FIG. 12C, a metal is deposited on a transparent thin film in order to form a thin film layer 250. The material of the metal may include Ag. At this point, the thickness of the thin film layer 250 may be less than the height of the colloidal bead scattered on the transparent thin film. The reason is that when the thickness of the thin film layer 250 is greater than the height of the colloidal bead, the thin film layer covers the colloidal beads, so that holes are not formed in the thin film layer 250.

Referring to FIG. 12D, then, the thin film layer 250 having the holes is completely formed by removing the colloidal beads 234. Substantially, that removing process is to remove the polymer beads remaining on the transparent thin film. Once the colloidal beads 234 are removed, the thin film layer 250 having the holes is formed on the transparent thin layer. The hole has the size of the colloidal bead 234 (Substantially, the hole has the size of the polymer bead, which is smaller than the size of the colloidal bead).

Referring to FIG. 12E, then, the upper first electrode 239 is stacked again on the thin film layer 250 in order to form a first electrode of a double layer having a thin film layer therebetween.

Referring to FIG. 12F, an organic light emitting layer 233 is stacked on the upper first electrode 239. If the first electrode includes a monolayer, the organic light emitting layer 233 is stacked on the bottom (i.e. the opposite side of the surface where the thin film layer 250 is stacked) of the first electrode having the thin film layer 250 stacked.

Referring to FIG. 12G, a second electrode 235 is stacked on the organic light emitting layer 233. When the second electrode 235 is used as a metal mirror layer of a micro-resonator, materials and thickness are selected and stacked in correspondence thereto.

According to the above method of manufacturing an organic light emitting device, a thin film layer including holes formed using colloidal beads may be easily manufactured.

As mentioned above, an organic light emitting device of the present invention includes a first electrode inside (i.e. anode-thin film layer-anode) having a double layer and a thin film layer for micro-resonator on at least one of first electrode outer surfaces. Therefore, light extraction efficiency may be improved.

Additionally, a plurality of holes are formed in a thin film layer, thereby preventing light from being blocked by a thin film layer that is additionally added for a micro-resonator. That is, transparency may be also improved.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An organic light emitting device comprising:
a light emitting part where a first electrode, an organic light emitting layer, and a second electrode are stacked; and
a thin film layer having a plurality of holes and micro-resonating the light emitted from the organic light emitting layer.

2. The organic light emitting device of claim 1, wherein the thin film layer comprises metal.

3. The organic light emitting device of claim 1, wherein the thin film layer is disposed on the first electrode.

4. The organic light emitting device of claim 1, wherein the thin film layer, the first electrode, and the organic light emitting layer are sequentially stacked.

5. The organic light emitting device of claim 3, wherein
the first electrode comprises a upper first electrode and a lower first electrode; and
the thin film layer is disposed between the lower first electrode and the upper first electrode.

6. The organic light emitting device of claim 1, wherein the thin film layer has a thickness of 20 nm to 100 nm.

7. The organic light emitting device of claim 1, wherein the hole has a diameter of 100 nm to 500 nm.

8. The organic light emitting device of claim 1, wherein the second electrode comprises, a metal layer having a plurality of holes

9. The organic light emitting device of claim 1, wherein the second electrode comprises a metal mirror layer.

10. A method of manufacturing an organic light emitting device, the method comprising:
forming a lower first electrode;
distributing colloidal beads on the lower first electrode;
growing a thin film layer by depositing metal on the lower first electrode;
forming a plurality of holes in the thin film layer by removing the colloidal beads; and
forming an upper first electrode, an organic light emitting layer, and a second electrode sequentially on the thin film layer.

11. The method of claim 10, wherein the thin film layer has a thickness less than a height of the colloidal beads distributed on the lower first electrode.
